(19) United States
(12) Patent Application Publication
(10) Pub. No.: US 2010/0289047 A1
(43) Pub. Date: Nov. 18, 2010

(54) Light Emitting Element and Illumination Device

(75) Inventors: Yoshiyuki Kawaguchi, Kyoto (JP); Kazuhiro Nishizono, Kyoto (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/680,884

(22) PCT Filed: Nov. 28, 2008
(86) PCT No.: PCT/JP2008/071729

§ 371 Date: May 18, 2010

(30) Foreign Application Priority Data
Nov. 29, 2007 (JP) 2007-308683

(51) Int. Cl. H01L 33/02; H01L 33/30; H01L 33/44

(52) U.S. Cl. 257/98; 257/103; 257/99; 257/E33.025; 257/E33.062; 257/E33.005; 257/E33.061

(57) ABSTRACT

Provided is a light emitting element capable of improving light extraction efficiency and suppressing the nonuniformity of emission intensity distribution over the entire surface of a light extraction surface. The light emitting element is provided with a semiconductor multilayer body having an n-type semiconductor layer and an emission layer and a p-type semiconductor layer, and an electrode pad connected to the p-type semiconductor layer. The semiconductor multilayer body has a large number of projections on one main surface thereof through which the light from the emission layer is emitted. The main surface of the semiconductor multilayer body has a first region located in the vicinity of the electrode pad, and a second region being further separated from the electrode pad than the first region. The interval between the projections in the second region is smaller than that in the first region.

### TECHNICAL FIELD

The present invention relates to a light emitting element, such as a light emitting diode (LED), and an illumination device.

### BACKGROUND ART

Recently, light emitting elements using a semiconductor such as a nitride-based semiconductor have been attracting attention.

Owing to low energy consumption and long luminous life of the light emitting elements using the semiconductor, these light emitting elements have been put into practice as a replacement for incandescent light bulbs or fluorescent lamps. However, the luminous efficiency of the light emitting elements using the semiconductor is lower than that of the fluorescent lamps, and hence they are required to achieve higher efficiency.

As a method of improving light extraction efficiency that is a technique for increasing the efficiency of the light emitting elements, there is, for example, a method of forming an concave and convex structure on the surface of a light emitting element (for example, refer to patent document 1). The light emitting element obtained by this method has concave and convex structures formed at certain intervals on one main surface of a semiconductor layer. These concave and convex structures cause light scattering to change the angle of reflection of reflected light, thereby increasing the rate in which the incident angle of light falls within the range of critical angle at the interface between the concave-and-convex structure and the exterior. This improves the efficiency of light extraction efficiency of the light emitting elements.

However, a p-type semiconductor layer has a higher electrical resistance than an n-type semiconductor layer and an emission layer. Therefore, the electrical current injected from an electrode pad disposed on the p-type semiconductor layer cannot be sufficiently diffused into the p-type semiconductor layer, and shows high emission intensity in the vicinity of the electrode pad. Consequently, a uniform emission intensity distribution cannot be obtained over the entire surface of the light emitting element.

Patent document 1: Japanese Unexamined Patent Application Publication No. 12-91639

### DISCLOSURE OF THE INVENTION

An advantage of the present invention is to provide a light emitting element adapted to improve the light extraction efficiency and suppress the nonuniformity of emission intensity distribution over the entire surface of a light extraction surface.

The light emitting element according to an embodiment of the present invention includes a semiconductor multilayer body having an n-type semiconductor layer and an emission layer and a p-type semiconductor layer, and an electrode pad connected to the p-type semiconductor layer. The semiconductor multilayer body has a large number of projections on one main surface thereof through which the light from the emission layer is emitted. The main surface of the semiconductor multilayer body has a first region located in the vicinity of the electrode pad, and a second region being further separated from the electrode pad than the first region. The interval between the projections in the second region is smaller than that in the first region.

### BRIEF DESCRIPTION OF THE DRAWINGS

FIG. 1 is a sectional view showing the light emitting element of an embodiment of the present invention;

FIG. 2 is a plan view when the light emitting element shown in FIG. 1 is viewed from above;

FIG. 3 is another sectional view showing the light emitting element of the embodiment of the present invention;

FIG. 4 is still another sectional view showing the light emitting element of the embodiment of the present invention;

FIG. 5 is a plan view when the light emitting element shown in FIG. 4 is viewed from above;

FIG. 6 is a sectional view showing an illumination device of an embodiment of the present invention;

FIG. 7 is a plan view in which the intensity distribution of rays passing through a light extraction surface in the light emitting element of Example 1 is plotted by computer simulation;

FIG. 8 is a plan view in which the intensity distribution of rays passing through a light extraction surface in the light emitting element of Comparative Example 1 is plotted by computer simulation;

FIG. 9 is a plan view in which the intensity distribution of rays passing through a light extraction surface in the light emitting element of Comparative Example 2 is plotted by computer simulation;

FIG. 10 is a plan view in which the intensity distribution of rays passing through a light extraction surface in the light emitting element of Comparative Example 3 is plotted by computer simulation;

FIG. 11 is a plan view in which the intensity distribution of rays passing through a light extraction surface in the light emitting element of Example 2 is plotted by computer simulation;

FIG. 12 is a sectional view showing the light emitting element of Comparative Example 1;

FIG. 13 is a sectional view showing the light emitting element of Comparative Example 2;

FIG. 14 is a sectional view showing the light emitting element of Comparative Example 3; and

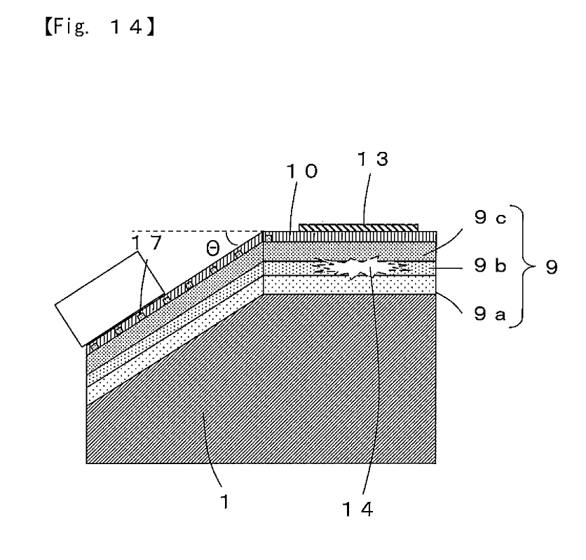

FIG. 15 is a plan view when the light emitting element shown in FIG. 14 is viewed from above.

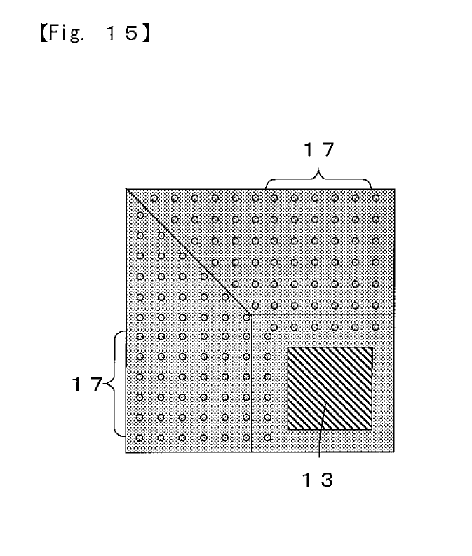

### PREFERRED EMBODIMENTS FOR CARRYING OUT THE INVENTION

Preferred embodiments of the light emitting element of the present invention will be described below in detail with reference to the drawings. The present invention is not limited to the following preferred embodiments.

### <Light Emitting Element of First Preferred Embodiment>

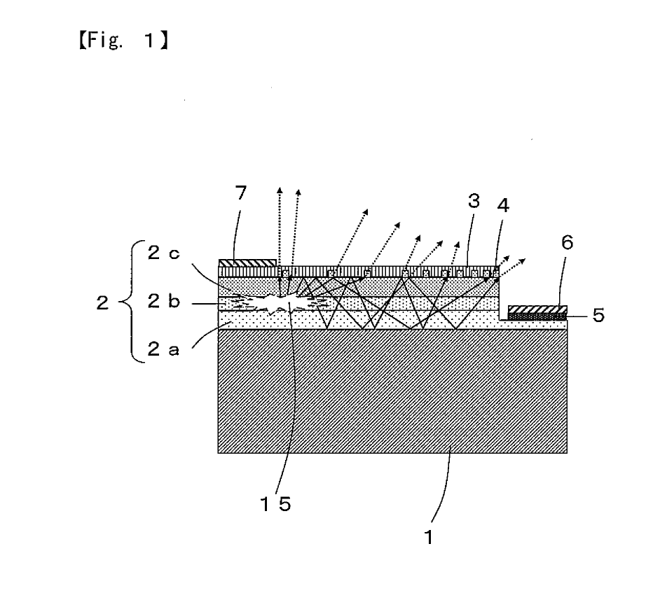

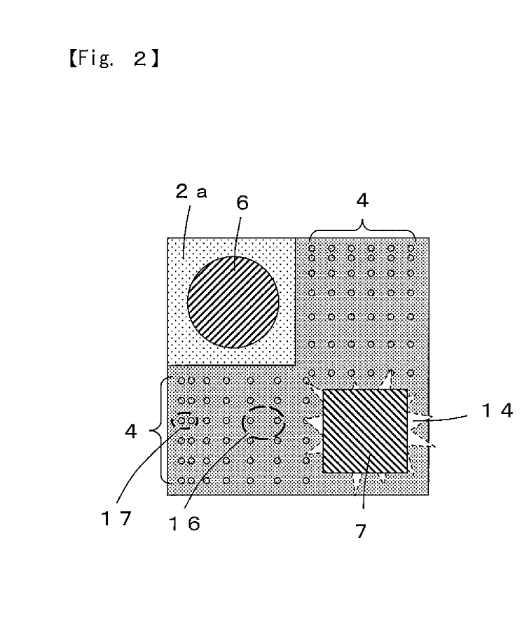

As shown in FIGS. 1 and 2, in the light emitting element of the present preferred embodiment, a semiconductor multilayer body 2 made up of an n-type semiconductor layer 2a and an emission layer 2b and a p-type semiconductor layer 2c is formed on a substrate 1. As a second conductive layer, a transparent conductive layer 3 is formed on the p-type semiconductor layer 2c. A p-electrode pad 7 as an electrode pad is formed on the transparent conductive layer 3. On the other hand, an n-electrode pad 5 as a first conductive layer is formed on the n-type semiconductor layer 2a. An individual n-electrode pad 6 for injecting an electrical current from the exterior is disposed on the n-electrode 5. The n-electrode pad 6 is connected to the wiring or the like of an external package by wire bonding.

A light emission center 14 is shown in FIGS. 1 and 2. The term “light emission center 14” indicates a region of the emission layer 2b in which the highest emission intensity is achieved. In the case of FIGS. 1 and 2, because the electrical resistance of the p-type semiconductor layer 2c is high, the electrical current from the p-type electrode pad is not sufficiently diffused, and the vicinity of the p-type electrode pad becomes the light emission center 14. As shown in FIG. 2, when the light emitting element is viewed from above, the light emission center 14 is overlapped with the electrode pad 7.

As shown in FIGS. 1 and 2, when the p-type semiconductor layer 2c has one main surface of the semiconductor multilayer body 2 through which the light from the emission layer 2b is emitted, a large number of projections 4 are formed on the main surface of the p-type semiconductor layer 2c.

As shown in FIG. 2, the main surface of the p-type semiconductor layer 2c has a first region 16 located in the vicinity of the p-electrode pad 7, and a second region 17 further separated from the p-electrode pad 7 than the first region 16. The first region and the second region denote the regions having different distances from the p-electrode pad and having two projections 4 adjacent to each other. The interval between the adjacent projections 4 in the second region 17 is smaller than that in the first region 16.

In the vicinity of the electrode pad having high emission intensity, the interval between adjacent projections is large, resulting in a small amount of light scattering. Accordingly, the light intensity is high in the vicinity of the electrode pad, but the amount of light scattering is small, so that the amount of light emitted to the exterior is lowered from a maximum intensity. On the other hand, at a position separated from the electrode pad, the interval between the projections in the second region is smaller than that in the first region, resulting in a large amount of light scattering. Accordingly, at the position separated from the electrode pad, though the light intensity itself is lowered, the amount of light scattering is large, thereby suppressing a decrease in the amount of light emitted to the exterior. Thus, the amount of light emitted from the region in the vicinity of the electrode pad, and the amount of light emitted from the region separated from the electrode pad can be adjusted respectively on the light extraction surface of the light emitting element.

As the first region 16, one interposed between the p-electrode pad 7 and the second region 17 is preferably used to compare the distance between their respective projections. Further, as two adjacent projections in the first region 16, and two adjacent projections in the second region 17, those located on the same straight line together with the p-electrode pad 7 are preferably used.

As shown in FIGS. 1 and 2, the interval between the adjacent projections 4 preferably decreases with increasing the distance from the p-electrode pad 7. The decrease in the amount of light emitted to the exterior can be suppressed with increasing the distance from the p-electrode pad 7, thereby suppressing the nonuniformity of the amount of light emitted to the exterior.

When the projections 4 are formed so that the interval therebetween becomes smaller with increasing the distance from the p-electrode pad 7, the interval between the adjacent projections 4 becomes preferably smaller in a proportional function manner or in an exponential function manner by using the distance from the p-electrode pad 7 as a variable. By so changing the interval between the projections 4, the amount of light scattering in the semiconductor layer 2 can be controlled depending on the distance from the p-electrode pad 7. Therefore, the emission intensity distribution, which has conventionally been enhanced in the vicinity of the p-electrode pad 7, can be made substantially uniform over the entire surface of the light extraction surface of the light emitting element.

For example, when the interval between the adjacent projections 4 is denoted by c, and the distance from the p-electrode pad 7 is denoted by d, and the interval c can be expressed in a proportional function manner by using the distance d as a variable, the interval c is derived as follows:

c=−a·d+cmax (provided a>0, and c>0)

where a denotes a rate in which the interval c between the projections 4 decreases depending on the distance d in the proportional function manner; and cmax denotes the value of c at a portion most adjacent to the p-electrode pad 7.

When the interval c can be expressed in an exponential function manner by using the distance d as a variable, the interval is derived as follows:

c=cmax×b^{ed} (provided 0≦b≦1, and e>0)

where b denotes a rate in which the interval c between the projections 4 decreases depending on the distance d in the exponential function manner; and e denotes an optional integer.

The cmax is usually in the range of 10 to 100 μm.

Examples of the shape of the projections 4 include cylinder, polygonal prism, circular cone, polygonal pyramid, partially circular cone (for example, circular truncated cone having a trapezoidal cross section), and partial polygonal pyramid (for example, having trapezoidal cross section). Examples of the shape of the top ends of the projections 4 include flat surface, projected curved surface, and cuspidal shape. As the shape of the top ends of the projections 4, particularly the projected curved surface or the cuspidal shape is preferable. Owing to the top ends of these shapes, the effective refractive index in the light emitting interface changes more gradually. Hence, the amount of reflection of the light in the emitting interface is decreased, and the amount of the light extracted is increased.

The length (average length) of the bottom sides of the projections 4 is preferably substantially equal to or below the effective wavelength in the p-type semiconductor layer 2c as an optical medium. The height (average height) of the projections 4 is preferably substantially equal to or more than the effective wavelength in the p-type semiconductor layer 2c. When the length of the bottom sides of the projections 4 and the height thereof are as described above, the refractive index difference between the p-type semiconductor layer 2c and the exterior thereof is smaller. Consequently, the reflection of light is suppressed, and the effect of light scattering is achieved. In the absence of the projections 4, beyond the critical angle, the total reflection of light occurs in the interface between the p-type semiconductor layer 2c and the exterior thereof, and the light is confined within the transparent conductive layer 3 or the semiconductor layer 2. However, when the length of the bottom sides of the projections 4 and the height thereof are as described above, the light propagation direction is changed by the projections 4, and the proportion of lights entering within the critical angle is increased, thereby improving the amount of light extracted.

The length (average length) of the bottom sides of the projections 4 is preferably larger than emission wavelength. If the length of the bottom sides of the projections 4 is shorter than the emission wavelength, the angular distribution of scattered light scattered by the projections 4 becomes narrow, and the angle of incidence at the interface connected to the exterior falls within the critical angle, thus decreasing the scattered light capable of being extracted outward. This makes it difficult to sufficiently achieve the effect of improving light extraction efficiency. The height (average height) of the projections 4 is preferably not more than 1.5 μm. If the height exceeds 1.5 μm, there is a tendency that it takes a long time to perform etching for forming the projections 4, thus lowering productivity.

The method of forming the projections 4 in FIG. 1 will now be described below. Firstly, the n-type semiconductor layer 2a, the emission layer 2b and the p-type semiconductor layer 2c are deposited successively on the substrate 1. Thereafter, concave and convex can be easily formed by depositing a mask made up of a resist layer, a metal layer or the like on the surface of the p-type semiconductor layer 2c, followed by etching the surface of the p-type semiconductor layer 2c by using etching method. Examples of the etching method include dry etching methods such as reactive ion etching (RIE), and wet etching method using etchant.

### <Semiconductor Multilayer Body>

In the semiconductor multilayer body 2, the emission layer 2b lies between the n-type semiconductor layer 2a and p-type semiconductor layer 2c. Examples of the semiconductor layer 2 include nitride semiconductors such as of gallium nitride. For example, when the n-type semiconductor layer 2a is a gallium nitride compound semiconductor layer, the gallium nitride compound semiconductor layer is composed of a multilayer body of a GaN layer as a first n-type clad layer and an In_{0.02}Ga_{0.98}N layer as a second n-type clad layer, or the like. The thickness of the n-type semiconductor layer 2a is approximately 2 μm to 3 μm.

Alternatively, when the p-type semiconductor layer 2c is a p-type gallium nitride compound semiconductor layer, the p-type gallium nitride compound semiconductor layer is composed of a multilayer body of an Al_{0.15}Ga_{0.85}N layer as a first p-type clad layer, an Al_{0.2}Ga_{0.8}N layer as a second p-type clad layer, and a GaN layer as a p-type contact layer, or the like. The thickness of the p-type semiconductor layer 2c is approximately 200 nm to 300 nm.

When the emission layer 2b is composed of the gallium nitride compound semiconductor, examples of the structure of the emission layer 2b include multi quantum well (MQW) structure. The MQW is obtained by repeating, for example, three times a regular alternate lamination of an In_{0.01}Ga_{0.99}N layer as a barrier layer having a large band gap, and an In_{0.11}Ga_{0.89}N layer as a well layer having a small band gap. The thickness of the emission layer 2b is approximately 25 nm to 150 nm.

As a method for growing the semiconductor multilayer body 2, metal organic vapor phase epitaxy (MOVPE) method is suitably employed. Alternatively, molecular beam epitaxy (MBE) method, hydride vapor phase epitaxy (HVPE) method, pulsed laser deposition (PLD) method, or the like.

The semiconductor multilayer body 2 is preferably disposed on the substrate 1, as shown in FIG. 1. Examples of the substrate 1 include substrates composed of a sapphire substrate, a nitride semiconductor, or the like. The substrate 1 is used as a substrate for growing the semiconductor multilayer body 2, and as a substrate for holding the light emitting element.

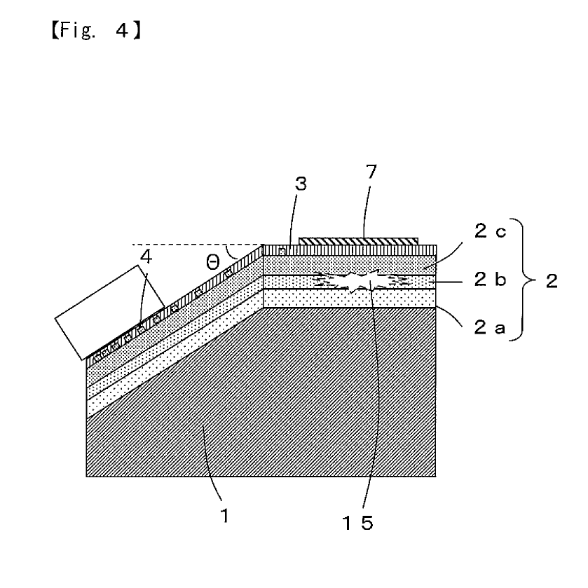

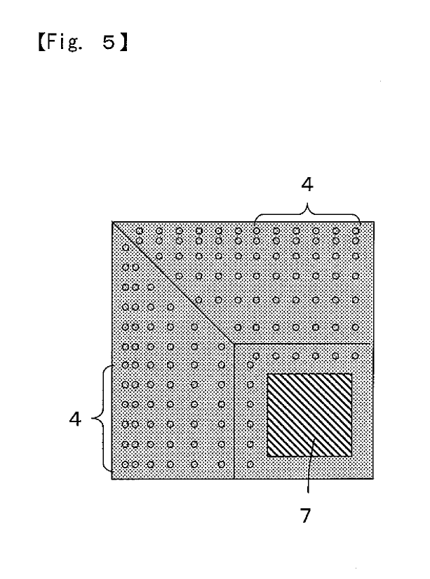

The semiconductor multilayer body 2 may have on its main surface an inclined surface as shown in FIG. 4. Owing to the inclined surface, the light emitting area is increased and the light extraction efficiency is improved. Additionally, the amount of light emission per unit area when viewed from above is also improved. In the light emitting element shown in FIG. 4, the interval between the adjacent projections 4 means the interval between the projections 4 when the light emitting element is viewed from above, as shown in FIG. 5.

The inclined surface preferably has an inclination angle of 10° to 80° (indicated by “θ” in FIG. 4) with respect to a noninclined surface of the upper surface of the substrate. The light extraction efficiency is improved by forming the inclined surface at the inclination angle of 10° to 80°.

The inclined surface is formed by subjecting the substrate 1 having the inclined surface to an etching method such as wet etching method with acid or alkaline by using a mask, or reactive ion etching (RIE) method, or alternatively to dicing method using a dicing blade whose top end has a desired angle.

### <Conductive Layer>

The light emitting element in the preferred embodiment of the present invention has a first conductive layer 5 and a second conductive layer 3. In the case of FIG. 1, the first conductive layer 5 designates an n-type electrode, and the second conductive layer 3 designates the transparent conductive layer 3.

The n-electrode is preferably composed of a material that reflects the light generated by the emission layer 2b without loss and makes a satisfactory ohmic contact to the n-type semiconductor layer 2a. Examples of the above material include aluminum (Al), titanium (Ti), nickel (Ni), chrome (Cr), indium (In), tin (Sn), molybdenum (Mo), silver (Ag), gold (Au), niobium (Nb), tantalum (Ta), vanadium (V), platinum (Pt), lead (Pb), beryllium (Be), indium oxide (In₂O₃), gold-silicon (Au—Si) alloy, gold-germanium (Au—Ge) alloy, gold-zinc (Au—Zn) alloy, and gold-beryllium (Au—Be) alloy. Among others, aluminum (Al) or silver (Ag) is preferred because of high reflectance with respect to lights from blue light (wavelength 450 nm) to ultraviolet light (wavelength 350 nm) emitted by the emission layer 2b. Additionally, aluminum (Al) is capable of establishing sufficient ohmic contact to the n-type semiconductor layer 2a, and hence is particularly suitable as the material of the n-electrode 5. Alternatively, the n-electrode 5 may be a multilayer body comprising a plurality of layers of a material selected from the above mentioned materials.

As the transparent conductive layer 3, metal oxides such as indium tin oxide (ITO), stannic oxide (SnO₂), and zinc oxide (ZnO) are used. Among others, indium tin oxide (ITO) is suitable because it has high transmittance with respect to ultraviolet light and blue light, and also makes a satisfactory ohmic contact to the p-type gallium nitride compound semiconductor layer 2c.

The thickness of the transparent conductive layer 3 is preferably 250 nm to 500 nm. When the thickness falls within this range, a satisfactory ohmic contact to the p-type gallium nitride compound semiconductor 2c is established. Additionally, the amount of light absorption in the transparent conductive layer 3 can be suppressed to thereby inhibit deterioration of the light extraction efficiency.

### <Electrode Pads>

An n-electrode pad 6 and a p-electrode pad 7 are disposed on the first conductive layer 5 and the second conductive layer 3, respectively. These electrode pads are those which connect conductor lines or the like for establishing an electrical connection with the exterior, respectively. As the n-electrode pad 6 and the p-electrode pad 7, for example, a titanium (Ti) layer, or a multilayer body formed by laminating a gold (Au) layer on a titanium (Ti) layer as a base layer may be used.

The light emitting element suitably using the semiconductor according to the present embodiment is usable as a light emitting diode (LED).

The light emitting element (LED) of the present embodiment is operated as follows. That is, by passing a bias current into the semiconductor multilayer body 2 including the emission layer 2b, ultraviolet light, near-ultraviolet light, or purple light of approximately wavelengths of 350 to 400 nm is generated in the emission layer 2b, and the above light is then extracted outside of the light emitting element.

### <Light Emitting Element of Second Preferred Embodiment>

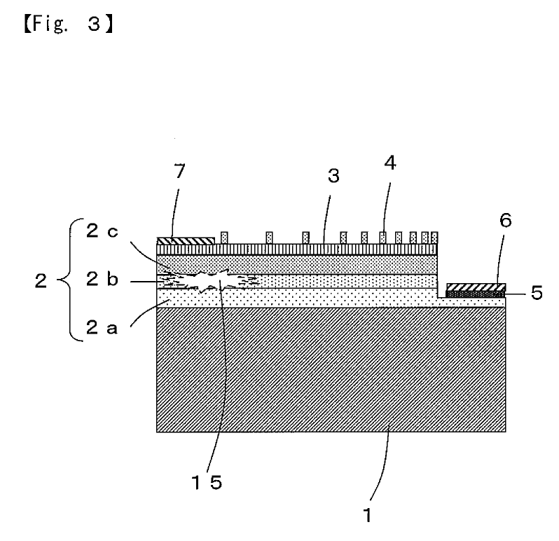

FIG. 3 shows the light emitting element of a second preferred embodiment of the present invention. In the light emitting element of the second preferred embodiment, either of the first conductive layer and the second conductive layer is the transparent conductive layer, and the main surface of the transparent conductive layer has a large number of projections. In FIG. 3, the second conductive layer 3 is the transparent conductive layer, and a plurality of projections 4 are disposed on the main surface thereof. In the light emitting element shown in FIG. 1, the projections 4 are disposed on the semiconductor multilayer body 2, whereas in the light emitting element shown in FIG. 3, the projections 4 are disposed on the transparent conductive layer. Otherwise, the configuration is the same as described above.

Similarly to the plan view shown in FIG. 2, the light emitting element of the second preferred embodiment has the first region 16 located in the vicinity of the p-electrode pad 7, and the second region 17 further separated from the p-electrode pad 7 than the first region 16. The interval between the adjacent projections 4 in the second region 17 is smaller than that in the first region 16. The effect achieved by this configuration is identical to that achieved by the light emitting element of the first preferred embodiment.

The semiconductor multilayer body 2, the first conductive layer 5, the second conductive layer 3 and the electrode pad 7 constituting the light emitting element of the second preferred embodiment are the same as those used in the light emitting element of the first preferred embodiment.

### <Illumination Device>

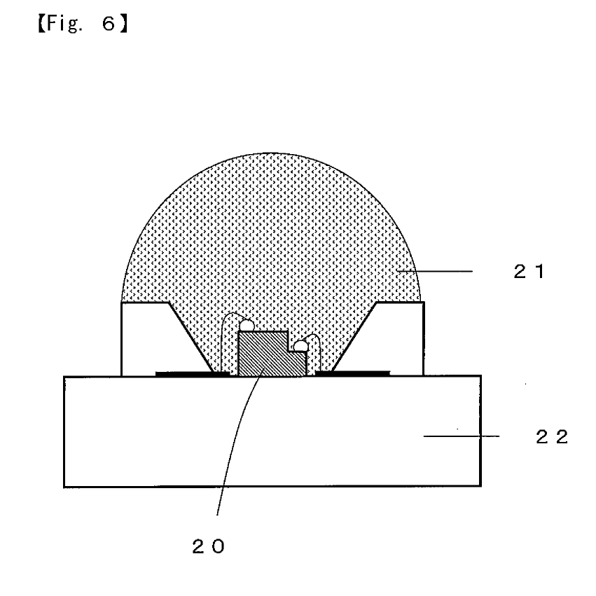

FIG. 6 is a drawing showing an illumination device equipped with the light emitting element of the present preferred embodiment. The illumination device covers or encases the light emitting element 20 of the present preferred embodiment with a transparent member 21 which is for example made of a transparent resin such as silicone resin, or glass. The illumination device is preferably adapted to incorporate a fluorescent body or a phosphorescent body into the transparent member 21. In the presence of the fluorescent body or the phosphorescent body in the transparent member 21, the ultraviolet light or the near-ultraviolet light generated from the light emitting element can be converted to white light or the like. Reference numeral 22 designates a mounting substrate.

Alternatively, a light reflecting member such as a concave mirror may be disposed on the transparent member 21 in order to enhance light focusing properties. The illumination device of this type consumes less power than conventional fluorescent lamps etc. and is compact, thus being useful as a compact and high-luminance illumination device.

### EXAMPLES

The following is an example (Example 1) of the light emitting element of the present preferred embodiment. In order to confirm the effect on the light extraction efficiency of the light emitting element of the present preferred embodiment, the computer simulations of the light emitting element shown in FIG. 1 was carried out using ray tracing method. These computer simulations can be carried out by using a “TracePro” manufactured by Lambda Research Corporation.

A simulation was carried out using the light emitting element shown in FIG. 2. The shape of the n-type gallium nitride compound semiconductor layer 2a when viewed from above was a square (310 μm×310 μm). A circular n-electrode 5 having a diameter of 120 μm connected to the n-type gallium nitride compound semiconductor layer 2a, and an n-electrode pad 6 connected to the n-electrode 5 were multilayered at the center of a corner part (170 μm×170 μm) which was partially exposed to the exterior, among the corner parts of the n-type gallium nitride compound semiconductor layer 2a. The n-electrode 5 was composed of nickel (Ni), and the n-electrode pad 6 was composed of gold (Au). A transparent conductive layer 3 composed of ITO was deposited so as to cover the upper surface of a p-type gallium nitride compound semiconductor layer 2c. Thereafter, a p-electrode pad 7 connected to the p-type gallium nitride compound semiconductor layer 2c was formed at a corner part on the upper surface of the transparent conductive layer 3. The p-electrode pad 7 was a square of 100 μm×100 μm and composed of gold (Au).

A large number of projections 4 (the number of the projections 4: 294) were formed on the upper surface of the p-type gallium nitride compound semiconductor layer 2c. When the interval between the adjacent projections 4 was denoted by c, and the distance from the end of the p-electrode pad 7 was denoted by d, and c can be expressed in a proportional function manner using d as a variable, the interval c is derived as follows: c=0.2d+45 (μm). That is, the value of c at the portion nearmost the p-electrode pad 7 (a maximum value cmax) was 45 μm, and c gradually became smaller with increasing d.

The individual projections 4 had a cone shape. The length (the maximum length) of the bottom sides of each projection 4 was 1 μm, and the height thereof was 1 μm.

The projections 4 were formed by depositing a mask made of a resist layer on the surface of the p-type gallium nitride compound semiconductor layer 2c, and then performing reactive ion etching (RIE) method.

The size of the light emitting element was a square whose side was 350 μm when viewed from above. The thickness of the substrate 1 was set to 350 μm, the thickness of the semiconductor multilayer body 2 was set to 3.4 μm, the thickness of the transparent conductive layer 3 was set to 0.25 μm, the thickness of the n-electrode 5 was set to 0.43 μm, and the thicknesses of the n-electrode pad 6 and the p-electrode pad 7 were set to 0.35 μm. A computer simulation was carried out by setting the emission wavelength to 400 nm, and setting so that 16000 rays were three-dimensionally and isotropically irradiated from the emission layer 2b immediately below the p-electrode pad 7.

A calculation was carried out by setting the refractive index of the transparent substrate 1 composed of sapphire to 1.76, the refractive index of the semiconductor multilayer body 2 to 2.5, the refractive index of the n-electrode 5 composed of nickel (Ni) to 1.61, and the refractive indexes of the n-electrode pad 6 and the p-electrode pad 7 each composed of gold (Au) to 1.66. In the semiconductor multilayer body 2, the n-type gallium nitride compound semiconductor layer 2a, the emission layer 2b and the p-type gallium nitride compound semiconductor layer 2c had little or no difference in the variation of refractive index, and hence the same refractive index was set to all of these layers.

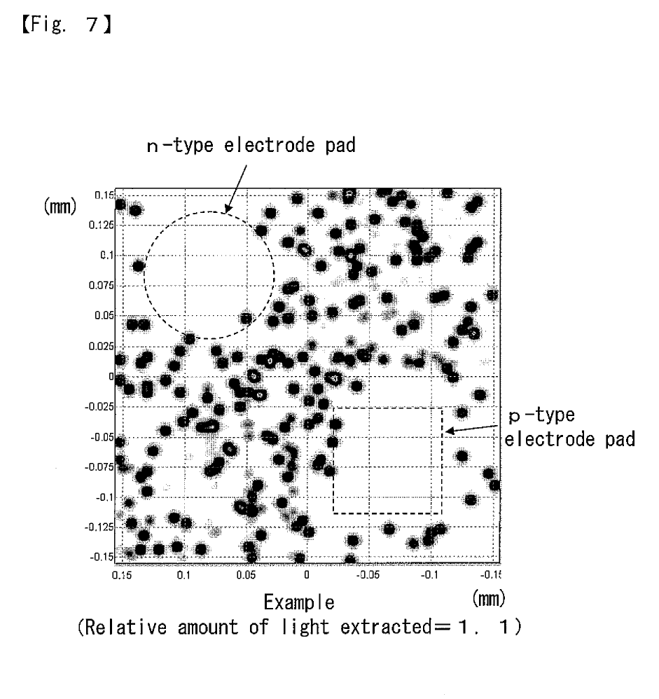

As a result, the intensity distribution of rays passing through the light extraction surface of the light emitting element was obtained as shown in FIG. 7. In FIG. 7, individual dots indicate the portions through which a ray passes, and large dots indicate high intensities.

### Comparative Example 1

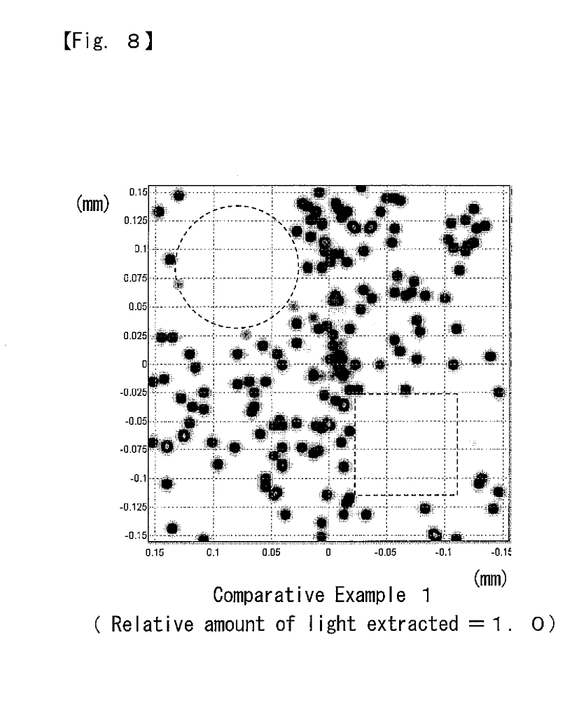

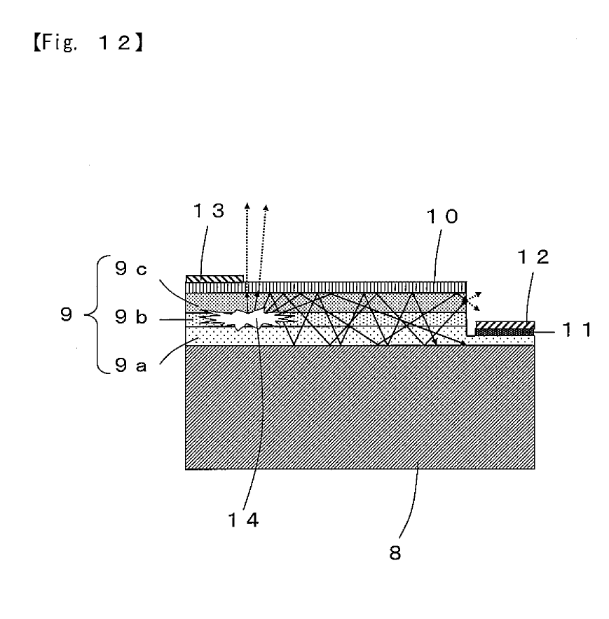

The light emitting element of FIG. 12 was manufactured similarly to Example 1 except that no projections 4 were disposed, and a computer simulation of light extraction efficiency was carried out. FIG. 12 shows the light emitting element of Comparative Example 1. As shown in FIG. 8, the intensity distribution of rays passing through the light extraction surface of the light emitting element was obtained by the simulation.

### Comparative Example 2

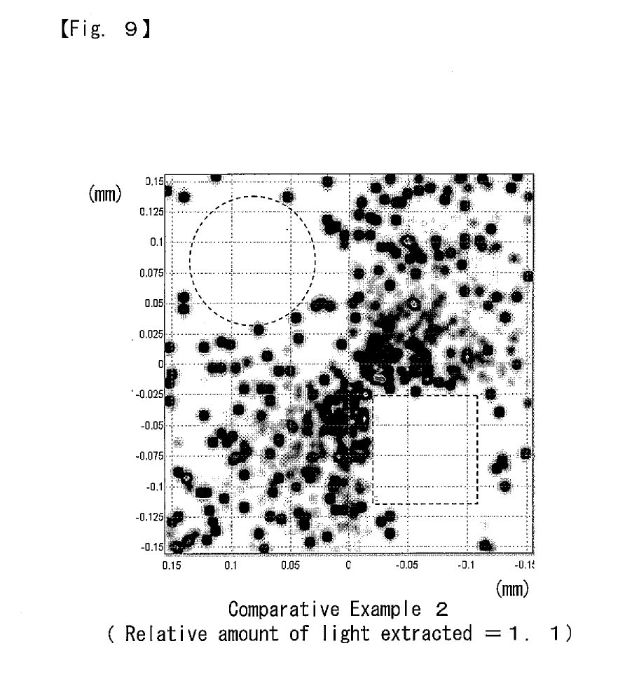

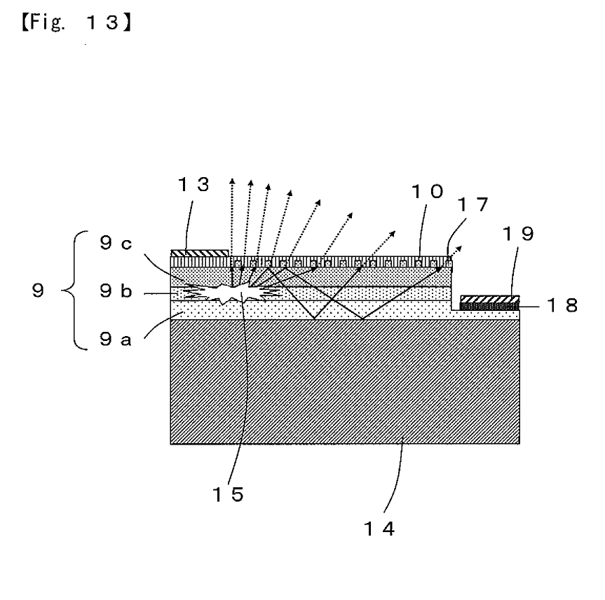

The light emitting element of FIG. 13 was manufactured similarly to Example 1 except that the interval between the projections 17 was constant at 5 μm, and a computer simulation of light extraction efficiency was carried out. As shown in FIG. 9, the intensity distribution of rays passing through the light extraction surface of the light emitting element was obtained by the simulation.

The followings were found from the results of the computer simulations in FIGS. 7 to 9. That is, the light emitting element of Example 1 achieved 1.1 times improvement in the amount of light extraction than the light emitting element of Comparative Example 1, and also achieved substantially uniform emission intensity over the entire surface of the light extraction surface. The light emitting element of Comparative Example 2 had the largest deviation of the emission intensity distribution in the vicinity of the p-electrode pad.

### Example 2

A simulation was carried out using the light emitting element shown in FIG. 4. The shape of an n-type gallium nitride compound semiconductor layer 2a when viewed from above was a square (340 μm×340 μm). A transparent conductive layer 3 composed of ITO was deposited so as to cover the upper surface of a p-type gallium nitride compound semiconductor layer 2c. Thereafter, a p-electrode pad 7 connected to the p-type gallium nitride compound semiconductor layer 2c was formed at a corner part of the upper surface of the transparent conductive layer 3. The p-electrode pad 7 was a square of 100 μm×100 μm and composed of gold (Au). A part of a substrate 1 was inclined so that the main surface of a semiconductor multilayer body 2 on the inclined surface of the substrate 1 was inclined 30 degrees with respective to a noninclined surface.

A large number of projections 4 were formed on the upper surface of the p-type gallium nitride compound semiconductor layer 2c. When the distance of the interval between the adjacent projections 4 (the distance when viewed from above) was denoted by d, and c can be expressed in a proportional function manner using d as a variable, the interval c is derived as follows: c=−0.2d+10 (μm). That is, the value of c at the portion nearmost the p-electrode pad 7 (a maximum value cmax) was 10 μm, and c gradually became smaller with increasing d.

Other conditions were the same as those in Example 1.

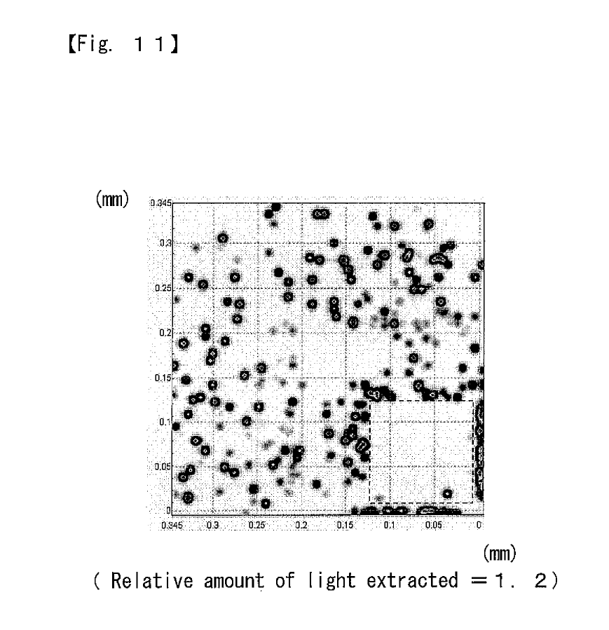

As a result, the intensity distribution of rays passing through the light extraction surface of the light emitting element was obtained as shown in FIG. 11. In FIG. 11, individual dots indicate the portions through which a ray passes, and large dots indicate high intensities.

### Comparative Example 3

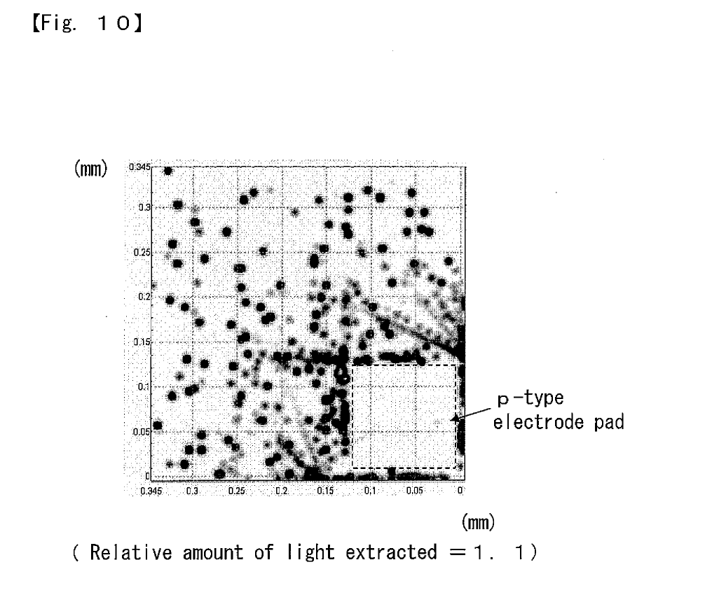

The light emitting element of FIG. 13 was manufactured similarly to Example 2 except that the interval between the projections 17 was constant at 10 μm, and a computer simulation of light extraction efficiency was carried out. As shown in FIG. 10, the intensity distribution of rays passing through the light extraction surface of the light emitting element was obtained by the simulation.

The followings were found from the results of the computer simulations in FIGS. 10 and 11. That is, the light emitting element of Example 2 achieved an improvement in the amount of light extraction than the light emitting element of Comparative Example 3, and also achieved substantially uniform emission intensity over the entire surface of the light extraction surface. The light emitting element of Comparative Example 3 had the largest deviation of the emission intensity distribution in the vicinity of the p-electrode pad.

1. A light emitting element, comprising:
a semiconductor multilayer body comprising an n-type semiconductor layer, an emission layer and a p-type semiconductor layer which are multilayered, and comprising a plurality of projections on a main surface thereof through which light from the emission layer is emitted;
a first conductive layer connected to the n-type semiconductor layer;
a second conductive layer connected to the p-type semiconductor layer; and
an electrode pad on the second conductive layer, which connects an exterior and the p-type semiconductor layer, wherein
the main surface of the semiconductor multilayer body comprises
a first region located in the vicinity of the electrode pad, and
a second region being further separated from the electrode pad than the first region and being disposed so that the first region is interposed between the electrode pad and the second region, and
an interval between the projections in the second region is smaller than that in the first region.

2. The light emitting element according to claim 1, wherein the interval of the projections becomes smaller with increasing the distance from the electrode pad.

3. The light emitting element according to claim 2, wherein the interval of the projections becomes smaller with increasing the distance from the electrode pad in a proportional function manner or in an exponential function manner when using the distance from the electrode pad as a variable.

4. The light emitting element according to claim 1, wherein a region with the highest emission intensity in the emission layer is overlapped with the electrode pad when the light emitting element is viewed from above.

5. The light emitting element according to claim 1, wherein the p-type semiconductor layer has the largest electrical resistance among the n-type semiconductor layer, the emission layer and the p-type semiconductor layer.

6. The light emitting element according to claim 1, wherein top ends of the projections are a convex curved surface or a pointed shape.

7. The light emitting element according to claim 1, wherein the main surface of the semiconductor multilayer body comprises an inclined surface.

8. The light emitting element according to claim 7, wherein the inclined surface has an inclination angle of 10° to 80° with respect to a non-inclined surface.

9. The light emitting element according to claim 1, wherein the semiconductor multilayer body comprises a gallium nitride based compound semiconductor.

10. The light emitting element according to claim 1, wherein the second conductive layer is a transparent conductive layer.

11. An illumination device, comprising:
the light emitting element according to claim 1; and
a fluorescent body and/or a phosphorescent body to emit light upon receipt of light emission from the light emitting element.

12. A light emitting element, comprising:
a semiconductor multilayer body comprising an n-type semiconductor layer, an emission layer and a p-type semiconductor layer which are multilayered;
a first conductive layer connected to the n-type semiconductor layer;
a second conductive layer connected to the p-type semiconductor layer; and
an electrode pad on the second conductive layer, which connects an exterior and the p-type semiconductor layer, wherein
either of the first conductive layer and the second conductive layer is a transparent conductive layer comprising a main surface through which light from the emission layer is emitted, and the main surface comprises a large number of projections thereon,
the main surface of the transparent conductive layer comprises a first region located in the vicinity of the electrode pad, and a second region being further separated from the electrode pad than the first region, and
an interval between the projections in the second region is smaller than that in the first region.

13. An illumination device, comprising:
the light emitting element according to claim 12; and
a fluorescent body and/or a phosphorescent body to emit light upon receipt of light emission from the light emitting element.
